(19) United States
(12) Patent Application Publication
(10) Pub. No.: US 2014/0283618 A1
(43) Pub. Date: Sep. 25, 2014

(54) SEMICONDUCTOR DEVICE AND STRAIN MONITOR

(71) Applicant: KABUSHIKI KAISHA TOSHIBA, Minato-ku (JP)

(72) Inventors: Takaaki Yasumoto, Kanagawa-ken (JP); Naoko Yanase, Tokyo (JP); Ryoichi Ohara, Hyogo-ken (JP); Shingo Masuko, Kanagawa-ken (JP); Kenya Sano, Hyogo-ken (JP); Yorito Kakiuchi, Hyogo-ken (JP); Takao Noda, Hyogo-ken (JP); Atsuko IIda, Kanagawa-ken (JP)

(73) Assignee: KABUSHIKI KAISHA TOSHIBA, Minato-ku (JP)

(21) Appl. No.: 14/019,266

(22) Filed: Sep. 5, 2013

(30) Foreign Application Priority Data
Mar. 21, 2013 (JP) 2013-057711

(51) Int. Cl. G01L 1/22; H01L 29/78

(52) U.S. Cl. CPC G01L 1/2293; H01L 29/78
USPC 73/777; 257/48

(57) ABSTRACT

According to one embodiment, a semiconductor device includes a substrate, a semiconductor substrate, an insulating gate field-effect transistor, and a strain gauge unit. The semiconductor substrate is placed on the substrate and has first and second regions. The insulating gate field-effect transistor is provided in the first region of the semiconductor substrate. The strain gauge unit has a long metal resistor, a first insulating film and a second insulating film. The long metal resistor is provided inside of an upper surface of the semiconductor substrate in the second region of the semiconductor substrate. The first insulating film is provided between the semiconductor substrate and the metal resistor and extends up to the upper surface of the semiconductor substrate. The second insulating film is provided above the first insulating film across the metal resistor.

### CROSS REFERENCE TO RELATED APPLICATION

This application is based upon and claims the benefit of priority from the prior Japanese Patent Application 2013-057711, filed on Mar. 21, 2013, the entire contents of which are incorporated herein by reference.

### FIELD

Embodiments described herein are generally related to a semiconductor device and strain monitor.

### BACKGROUND

Conventionally, as a power semiconductor device used for a motor control circuit, electric power conversion equipment, and the like, there is known a power semiconductor device having a power semiconductor element bonded to a copper base substrate with a solder layer interposed therebetween, and a metal foil strain gauge provided on a surface of the power semiconductor element.

When the power semiconductor element generates heat by electric power supplied to the power semiconductor element, a thermal strain is generated to the power semiconductor element and in the vicinity of the power semiconductor element due to a difference between thermal expansion coefficients of silicon (Si), solder alloy, and copper (Cu). The strain gauge monitors a strain amount of the thermal strain.

However, a silicon carbide (SiC) power semiconductor element which is considered promising as a next-generation power semiconductor element has a use temperature (200° C. to 400° C.) higher than that of a silicon power semiconductor element (100° C. to 150° C.).

The high use temperature causes a deterioration of a strain gauge, so that characteristics of the strain gauge, such as sensitivity, response, and the like are lowered. Accordingly, there is a problem in that reliability of the SiC power semiconductor device is lowered.

### BRIEF DESCRIPTION OF THE DRAWINGS

FIG. 1 is a sectional view showing a semiconductor device according to a first embodiment.

FIGS. 2A and 2B are views showing a semiconductor element employed to the semiconductor device according to the first embodiment.

FIG. 3 is an enlarged sectional view showing a strain gauge unit provided to the semiconductor element according to the first embodiment.

FIG. 4 is a view showing a strain monitor according to the first embodiment.

FIG. 5 is a flowchart showing an operation of the strain monitor according to the first embodiment.

FIGS. 6A to 6C, 7A to 7C, and 8 are sectional views showing steps of manufacturing the strain gauge unit in sequential order according to the first embodiment.

FIG. 9 is a plan view showing a semiconductor element employed to a semiconductor device according to a second embodiment.

FIG. 10 is a plan view showing another semiconductor element employed to the semiconductor device according to the second embodiment.

### DETAILED DESCRIPTION

According to one embodiment, a semiconductor device includes a substrate, a semiconductor substrate, an insulating gate field-effect transistor, and a strain gauge unit. The semiconductor substrate is placed on the substrate and has first and second regions. The insulating gate field-effect transistor is provided in the first region of the semiconductor substrate. The strain gauge unit has a long metal resistor, a first insulating film and a second insulating film. The long metal resistor is provided inside of an upper surface of the semiconductor substrate in the second region of the semiconductor substrate. The first insulating film is provided between the semiconductor substrate and the metal resistor and extends up to the upper surface of the semiconductor substrate. The second insulating film is provided above the first insulating film across the metal resistor.

Embodiments will be described below with reference to the drawings. In the drawings, the same reference numerals show the same or similar portions. The same portions in the drawings are denoted by the same numerals and a detailed explanation of the same portions is appropriately omitted, and different portions will be described.

### First Embodiment

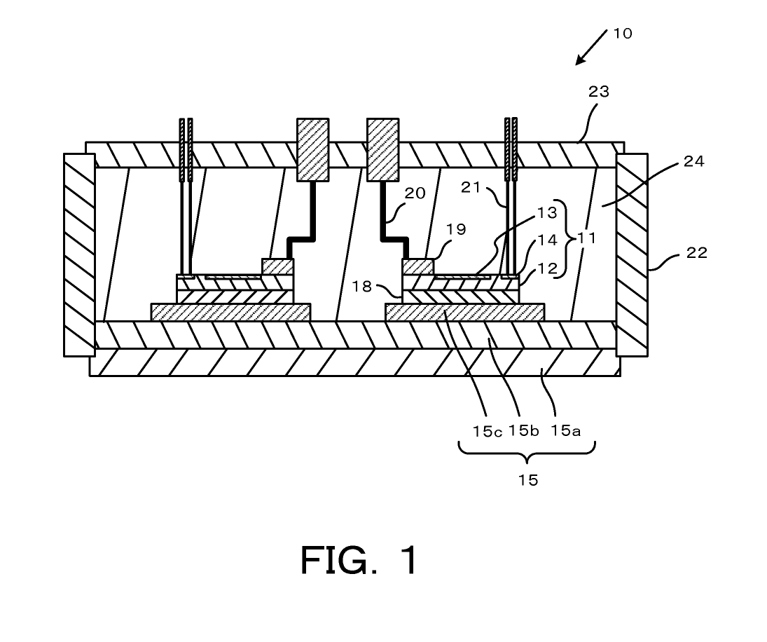

A semiconductor device in accordance with a first embodiment will be described with reference to FIG. 1 to FIG. 3. FIG. 1 is a sectional view showing the semiconductor device of the embodiment.

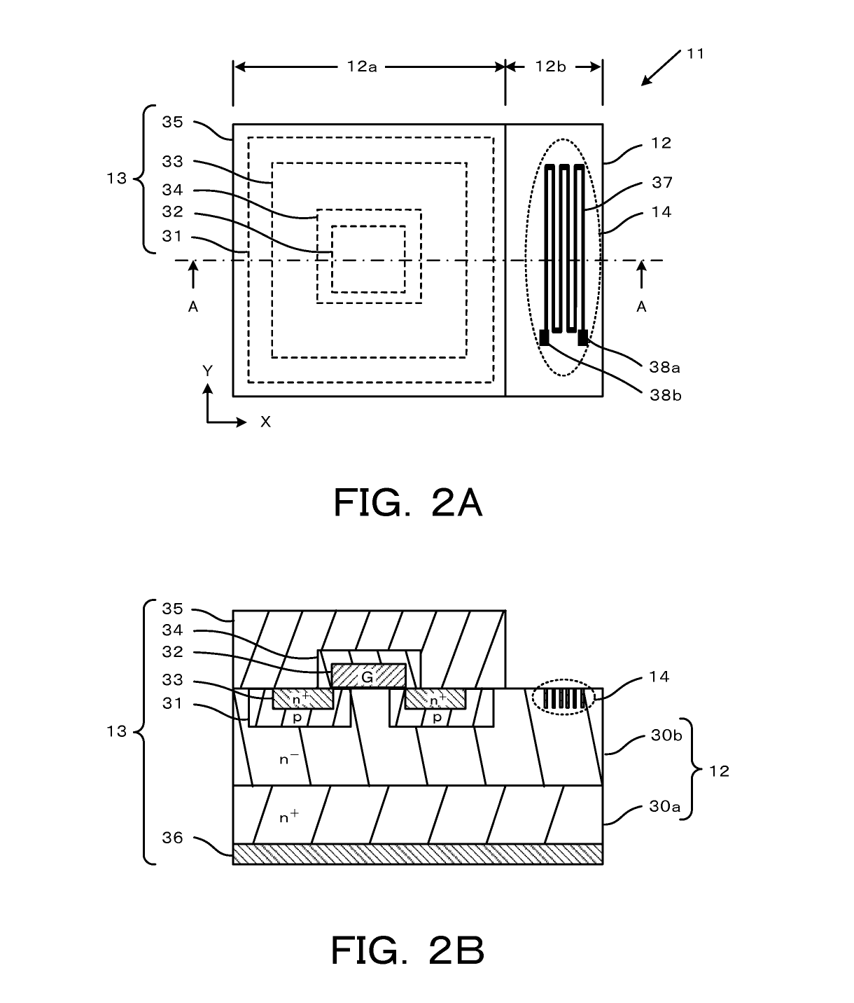

FIGS. 2A and 2B are views showing a semiconductor element employed to the semiconductor device. FIG. 2A is a plan view of the semiconductor element. FIG. 2B is a sectional view of the semiconductor element taken along a line A-A of FIG. 2A and viewed in an arrow direction.

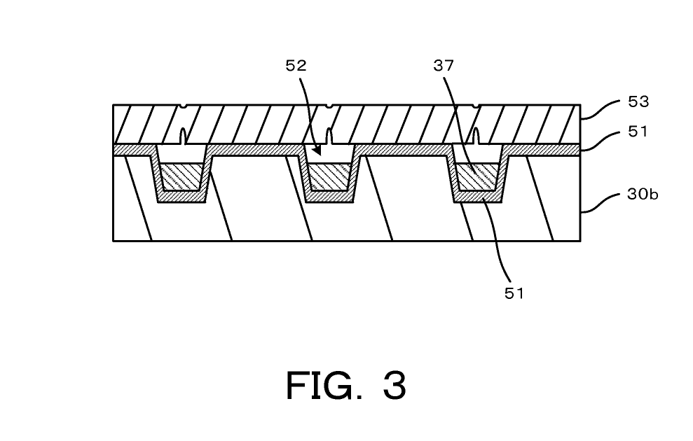

FIG. 3 is an enlarged sectional view showing a strain gauge unit provided with the semiconductor element.

As shown in FIG. 1, the semiconductor device 10 of the embodiment is a silicon carbide (SiC) power semiconductor device used for a motor control circuit, electric power conversion equipment, and the like which operate at high electric power. The semiconductor element 11 is a SiC semiconductor element. The semiconductor device 10 is a so-called 2 in 1 semiconductor device on which two semiconductor elements 11 are mounted.

In the semiconductor element 11, an insulating gate field-effect transistor (MOS transistor) 13 to switch high electric power and a strain gauge unit 14 to monitor a thermal strain of the SiC semiconductor substrate 12 due to heat generation by electric power supplied to MOS transistor 13 are monolithically provided to the semiconductor substrate 12.

The semiconductor substrate 12 is placed on a substrate 15 via a solder layer 18. The substrate 15 has a copper base substrate 15a, an insulating layer 15b, and a circuit pattern 15c. The insulating layer 15b is provided on the copper base substrate 15a, and the circuit pattern 15c is provided on the insulating layer 15b. The semiconductor substrate 12 is electrically connected to the circuit pattern 15c.

A source electrode (not shown) of the MOS transistor 13 is connected to a lead frame 20 via a solder layer 19. Gauge terminals (not shown) of the strain gauge unit 14 are connected to gauge leads 21.

The substrate 15 is attached with a cylindrical case 22. A lid member 23 is attached to the cylindrical case 22. A box-shaped package for accommodating the semiconductor element 11 is configured by the substrate 15, the case 22, and the lid member 23. The package is filled with a resin 24. The lead frame 20 and the gauge leads 21 are drawn out to the outside from the lid member 23 side.

Further, the substrate 15 is attached with a radiation means (not shown), for example, a radiation fin. The heat generated in the MOS transistor by being supplied with the electric power is transmitted to the radiation fin mainly through the substrate 15 and radiated to the outside.

As shown in FIG. 2A, the semiconductor substrate 12 has an n⁺ type SiC substrate 30a and an n⁻ type SiC semiconductor layer 30b provided on the SiC substrate 30a. The semiconductor substrate 12 has a first region 12a and a second region 12b which are adjacent to each other.

The MOS transistor 13 is provided in the first region 12a, and the strain gauge unit 14 is provided in the second region 12b. The first region 12a is larger than the second region 12b.

The MOS transistor 13 is a vertical MOS transistor. The SiC substrate 30a is a drain layer, and the SiC semiconductor layer 30b is a drift layer in which electrons travel. A frame-like p-type base layer 31 is provided in the first region 12a of the SiC semiconductor layer 30b.

A gate electrode 32 is provided on a region in which a channel of a p-type base layer 31 is formed though a gate insulating film (not shown). An n⁺-type impurity diffusion layer 33 is provided to the base layer 31 so as to surround the gate electrode 32. The impurity diffusion layer 33 is a source layer.

The gate electrode 32 is covered with an interlayer dielectric film 34 and drawn out to the outside. A source electrode 35 is provided on the impurity diffusion layer 33. A drain electrode 36 is provided on the SiC substrate 30a.

The strain gauge unit 14 is a metal strain gauge provided in the SiC semiconductor layer 30b, the metal strain gauge extending in a Y-direction and having a metal resistor (Ni—Cr alloy film) 37 which is formed in a shape alternately bent in an opposite direction (±Y-direction).

Both the ends of the metal resistor 37 are drawn out onto the SiC semiconductor layer 30b and connected to the gauge terminals 38a, 38b provided on the SiC semiconductor layer 30b.

As shown in FIG. 3, the metal resistor 37 is buried into a trench via a first insulating film 51, the trench extending in the Y-direction in the SiC semiconductor layer 30b and being formed in a shape alternately bent in an opposite direction (±Y-direction). An upper surface of the metal resistor 37 is lower than an upper surface of the SiC semiconductor layer 30b.

The metal resistor 37 is provided inside of the upper surface of the SiC semiconductor layer 30b. The first insulating film 51 is provided between the SiC semiconductor layer 30b and the metal resistor 37 and extends up to the upper surface of the SiC semiconductor layer 30b.

A second insulating film 53 which covers an opening of the trench away from the metal resistor 37 is provided on the first insulating film 51 to form a cavity (void) 52 between the second insulating film 53 and the metal resistor 37. The second insulating film 53 is provided on the first insulating film 51 across the metal resistor 37.

A metal material has a resistance value inherent to the metal material and is expanded (or contracted) by a tensile force (compression force) applied thereto from the outside, and a resistance value of the metal material is increased (or reduced). When it is assumed that the resistance value R of the metal material is varied by ΔR at the time force is applied thereto, the following relation will be established.

ΔR/R=Ks·ΔL/L=Ks·∈ (1)

where, Ks is a coefficient (gauge factor) showing a sensitivity of the strain gauge, L is a length of the metal resistor 37, and ΔL is a change amount of the length of the metal resistor 37. Copper-Nickel alloy and Nickel-Chromium alloy which are used for an ordinary strain gauge have a gauge factor of approximately 2.

The cavity 52 is provided to prevent the metal resistor 37 from coming into contact with the resin 24 shown in FIG. 1. The contact between the metal resistor 37 and the resin 24 causes the following disadvantages.

The resin 24 relatively applies force to the metal resistor 37 due to a difference of thermal expansions between the resin 24 and the metal resistor 37. The force acts as noise when a fatigue of the solder layer 18 which connects the semiconductor substrate 12 to the substrate 15 is detected.

Further, a remaining gas, for example, an oxygen gas and the like in the resin 24 is in contact with the metal resistor 37 at a high temperature (200° C. to 400° C.) and reacted with the metal resistor 37, thereby the metal resistor 37 is degraded. As a result, there is a possibility that characteristics of the strain gauge unit 14, such as detection sensitivity and response are lowered.

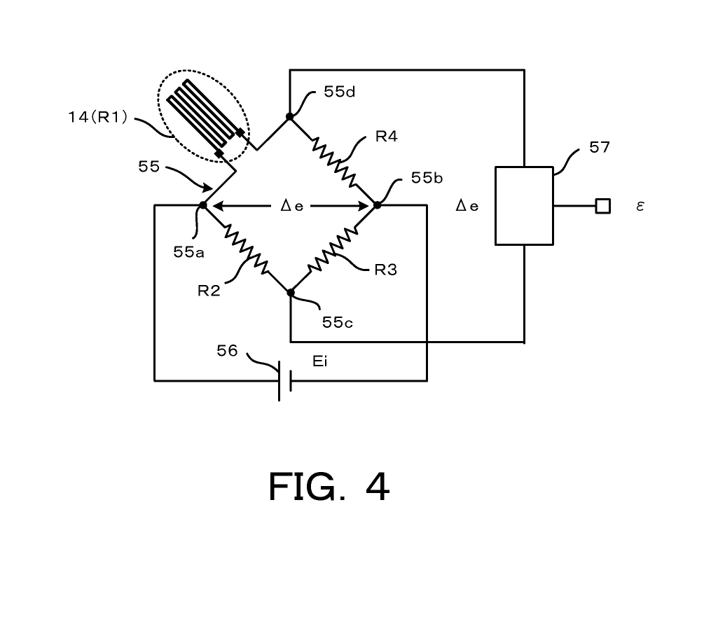

FIG. 4 is a view showing a strain monitor to monitor strain in the semiconductor device 10 using the strain gauge unit 14. The strain is detected by a Wheatstone bridge (strain measurement device) 55. The strain gauge unit 14 configures the Wheatstone bridge 55 together with resistors R2, R3, R4.

It is assumed here that the strain gauge unit 14 is composed of a resistor R1. A power supply 56 to output a voltage Ei is connected between a connection node 55a of the resistors R1, R2 and a connection node 55b of the resistors R3, R4. A signal processing device 57 is connected between a connection node 55c of the resistors R2, R3 and a connection node 55d of the resistors R4, R1.

The signal processing device 57 calculates a strain amount ∈ by reading an output voltage Δe (non-equilibrium potential difference) of the Wheatstone bridge 55 and outputs the calculated strain amount ∈. The output voltage Δe of the Wheatstone bridge 55 is shown by the following expression.

ΔVe=Ei(R1R3−R2R4)/{(R1+R4)(R2+R3)} (2)

When it is assumed here that resistance values of the resistor R1 to the resistor R4 are equal with each other (R1=R2=R3=R4), the value ΔVe is shown by the following expression.

ΔVe=(ΔR/4R1)Ei=Ks·∈·Ei/4 (3)

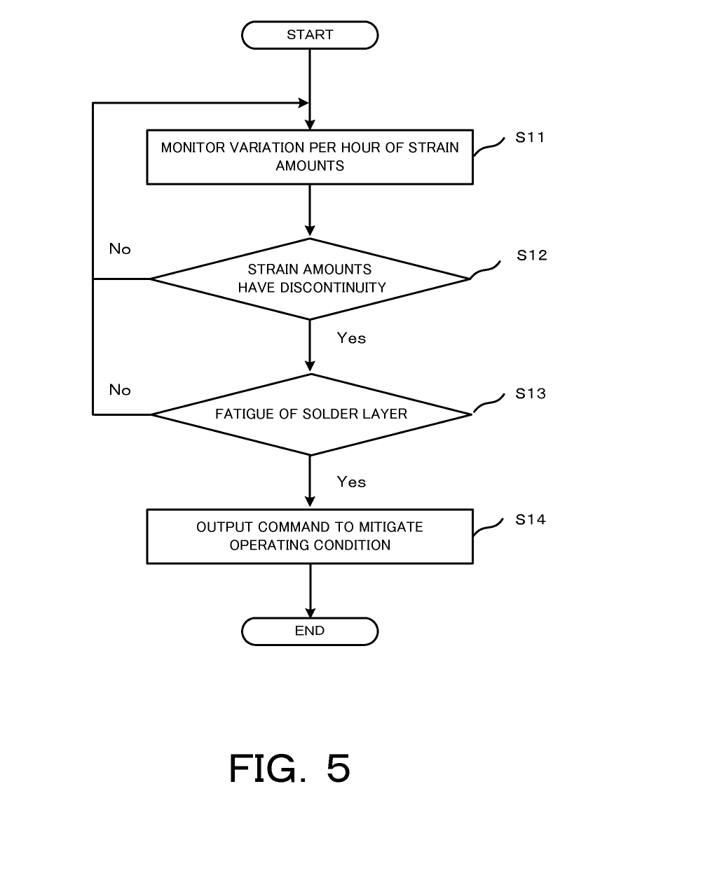

FIG. 5 is a flowchart showing an operation of the strain monitor. Here, as an example, a case where strain amounts detected by the strain gauge unit 14 are continuously monitored in advance to prevent a failure of the semiconductor device 10 from occurring due to fatigue breakdown of the solder layer 18 will be described.

It is assumed that a predetermined amount of electric power is repeatedly supplied to the semiconductor device 10 for a long period. It is also assumed that the signal processing device 57 is built-in with a microprocessor and a storage device, strain amounts detected by the strain gauge unit 14 are stored in the storage device, and data of the strain amounts obtained at fatigue breakdown of the solder layer 18 in the past is stored.

A variation per hour of strain amounts is monitored (step S11). The strain amount detected by the strain gauge unit 14 is stored in the storage device of the signal processing device 57 and accumulated as the variation per hour.

The strain amount detected by the strain gauge unit 14 is compared with the variation per hour of the strain amounts stored heretofore and whether or not the strain amounts have an unnatural discontinuity is determined (step S12).

When the strain amounts have no unnatural discontinuity (No in step S12), a process returns to step S11 and strain amounts are continuously monitored. In contrast, when the strain amounts have an unnatural discontinuity (Yes in step S12), the process goes to step S13.

The variation per hour of the strain amounts is compared with the data of the strain amounts which is obtained at fatigue breakdown of the solder layer 18 in the past and is stored in the signal processing device 57, and fatigue characteristics of the solder layer are determined (step S13).

When the fatigue characteristics of the solder layer 18 have not exceeded a reference value in which it is supposed that the fatigue characteristics reach the breakdown due to fatigue (NO in step S13), the process returns to step S11 and strain amounts are continuously monitored. In contrast, when the fatigue characteristics of the solder layer 18 have exceeded the reference value in which it is supposed that the fatigue characteristics reach the breakdown due to fatigue (Yes in step S13), a command to mitigate operating conditions of the semiconductor device 10 is output (step S14).

The mitigation of the operating condition means to review an operating condition of the MOS transistor 13, or to use a different semiconductor element 11 built-in the semiconductor device 10 as a spare (backup) and to switch a power supply to the semiconductor element 11 acting as the spare, for example.

The failure of the semiconductor device 10 caused by breakdown due to fatigue of the solder layer 18 can be prevented before it is generated. Accordingly, the semiconductor device 10 having high reliability can be obtained.

When a fatigue is accumulated in the solder layer 18, the solder layer 18 gradually becomes brittle. When a stress is applied to the solder layer 18 being brittle, micro cracks are generated. When the micro cracks have been generated to the solder layer 18, since a strain generated to the solder layer 18 is partly released, the micro cracks can be observed as a change of the strain amount. When a density of the micro cracks exceeds a certain limit, the solder layer 18 is cracked and broken.

A method of manufacturing the semiconductor device 10 will be described. Since manufacturing steps of the MOS transistor 13 of the semiconductor element 11 and assembly steps of the semiconductor device 10 are known well, an explanation of the manufacturing steps and assembly steps is omitted and manufacturing steps of the strain gauge unit 14 will be described.

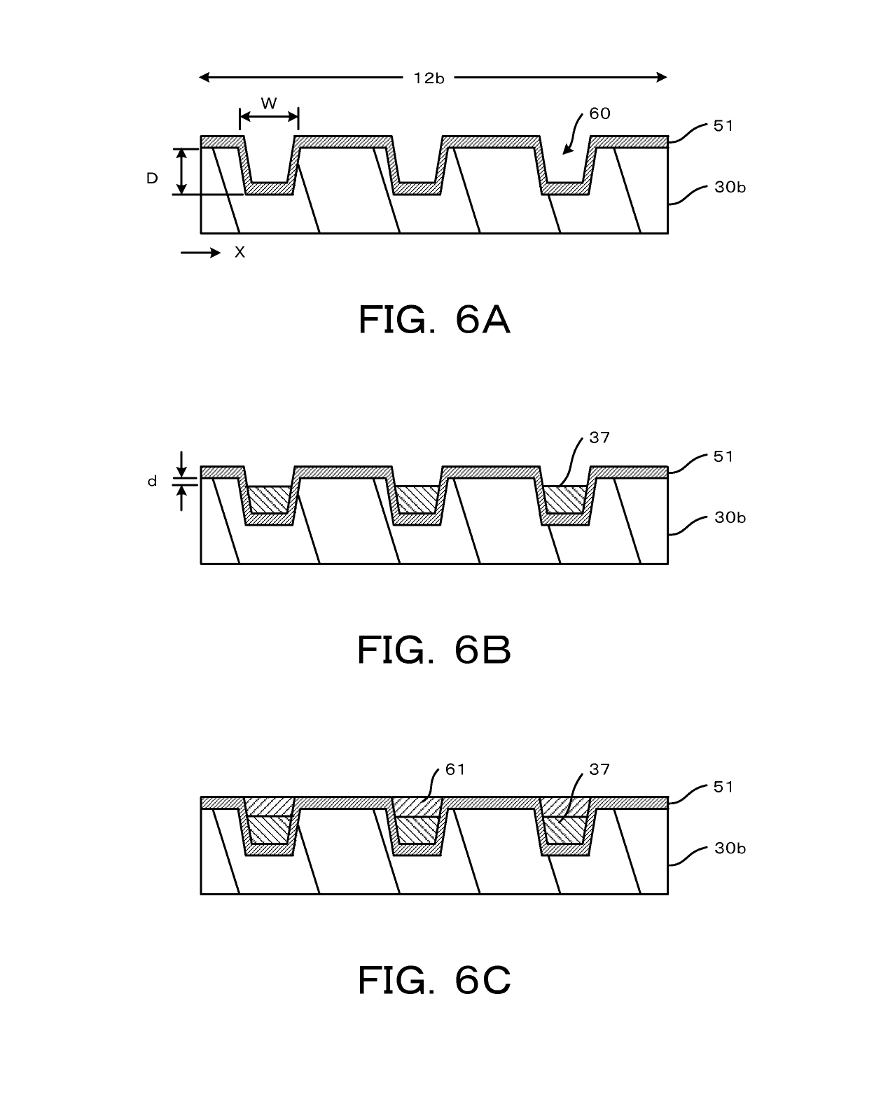

FIGS. 6A to 6C, 7A to 7C, and 8 are sectional views sequentially showing the manufacturing steps of the strain gauge unit 14. The manufacturing steps of the strain gauge unit 14 can be entirely or partly executed simultaneously with the manufacturing steps of the MOS transistor 13.

The SiC semiconductor layer 30b is formed on the SiC substrate 30a by MOCVD (Metal Organic Chemical Vapor Deposition), for example. The SiC semiconductor layer 30b having a 4H structure is epitaxially grown on the SiC substrate 30a having a 4H structure, for example, using an argon (Ar) gas, for example, as a carrier gas, using a silane (SiH₄) gas and propane (C₃H₈) gas, for example, as a process gas, and using a nitrogen (N₂) gas, for example, as a n-type dopant.

As shown in FIG. 6A, a resist film (not shown) which extends in the Y-direction shown in FIG. 2 and has an opening formed in a shape alternately bent in an opposite direction (±Y-direction) is formed in the second region 12b of the SiC semiconductor layer 30b by photolithography.

Using the resist film as a mask, a trench 60 is formed which extends in the Y-direction and has a shape alternately bent in an opposite direction (±Y-direction) by RIE (Reactive Ion Etching) using a fluorine gas (CF₄ and the like), for example.

It is sufficient that the trench 60 has a width, a depth, and an entire length which allow the metal resistor 37 to have a resistance value to act as the strain gauge. It is sufficient that the trench 60 is within a range in which the width W is 500 nm to 100 μm, the depth D is 10 nm to 100 μm, and the entire length is 50 nm to 2 mm, for example.

A silicon oxide film having a thickness of 200 nm, for example, is conformally formed on the SiC semiconductor layer 30b as the first insulating film 51. The silicon oxide film is formed by subjecting the SiC semiconductor layer 30b to thermal oxidation, plasma CVD, LP (Low Pressure)-CVD or the like.

As shown in FIG. 6B, a Ni—Cr alloy film is formed on the SiC semiconductor layer 30b as the metal resistor 37 so as to fill the trench 60 by sputtering, for example.

Although the Ni—Cr alloy film has various compositions, a Ni—Cr alloy film containing Ni in the range of 50 to 80 wt % and Cr in the range of 20 to 50 wt % can be used. In particular, when an importance is put on temperature characteristics, the metal resistor 37 may be composed of NiCrSiO₂ alloy film.

The Ni—Cr alloy film is removed until the first insulating film 51 is exposed by CMP (Chemical Mechanical Polishing). A CMP apparatus, a polishing slurry, and the like which are used to manufacture an ordinary semiconductor device can be used.

At the time, an upper surface of the metal resistor 37 is dug down lower than the upper surface of the SiC semiconductor layer 30b by a depth d for the cavity 52 shown in FIG. 3 making use of etch back and the like by dishing or wet etching accompanied with CMP.

The depth d is appropriately set to a range of 50 to 90% of a depth D of the trench 60. A contact of the second insulating film 53 and the metal resistor 37 may occur when the second insulating film 53 which configures the cavity 52 shown in FIG. 3 is flexed as a membrane at the time the depth d exceeds 90% of the depth D of the trench 60.

When the depth d is less than 50% of the depth D of the trench 60, it becomes difficult to uniformly dig down the metal resistor 37 by the dishing or the wet etching described above.

As shown in FIG. 6C, a polysilicon film 61 is formed on the first insulating film 51 and on the metal resistor 37 by LP-CVD, for example. Although it is preferable that the polysilicon film 61 is not doped, a phosphorus (P)-doped polysilicon film can be also used. However, since phosphorus having a high density reacts to Ni of the metal resistor 37 (Ni—Cr alloy) to create a Ni—P compound, it is preferable that phosphorus has a low density.

The polysilicon film 61 is removed by CMP until the first insulating film 51 is exposed. The polysilicon film 61 is left only on the metal resistor 37 in the trench 60. The polysilicon film 61 is a sacrificing layer to form the cavity 52 shown in FIG. 3.

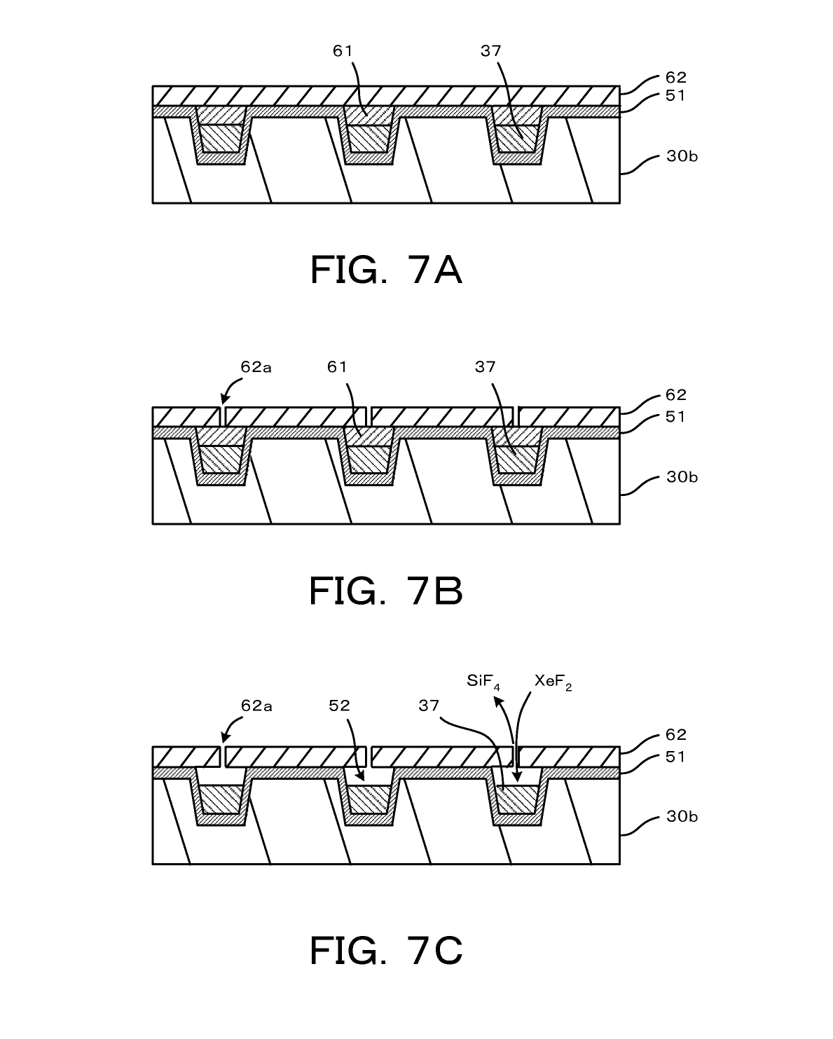

As shown in FIG. 7A, a silicon oxide film 62 having a thickness of 200 nm is formed on the first insulating film 51 and on the polysilicon film 61 by plasma CVD or LP-CVD, for example. The silicon oxide film 62 becomes a portion of the second insulating film 53 shown in FIG. 3.

It is sufficient that the silicon oxide film 62 has a thickness which allows a through groove for etching the sacrificing layer to be formed and prevents an occurrence of a discontinuous step caused by swelling and warping of a substrate.

As shown in FIG. 7B, a resist film (not shown) having an opening with a width smaller than a width W of the trench 60 is formed on the silicon oxide film 62 by photolithography in confrontation with the polysilicon film 61.

The silicon oxide film 62 is etched using the resist film as a mask to form a through groove 62a which reaches the polysilicon film 61. The silicon oxide film 62 is etched by wet etching using buffered hydrogen fluoride (BHF) and/or RIE using a fluorine gas, for example. Any one or both of the wet etching and the RIE can be used depending on a ratio of a depth and a width of the through groove 62a.

It is sufficient to form the through groove 62a in a shape which can set the ratio of the depth and the width to 2 or more. It is not necessary to vertically form side surfaces of the through groove 62a and it is preferable that the side surfaces are gradually away from each other upward. When these requirements are not satisfied, sealing of the through groove 62a to be described later becomes difficult.

As shown in FIG. 7C, the polysilicon film 61 that is the sacrificing layer is removed by dry etching using fluoro-xenon (XeF₂) gas, for example. The polysilicon film 61 reacts to XeF₂ diffused and flown via the through groove 62a and becomes volatile SiF₄.

SiF₄ is vaporized to the outside via the through groove 62a. Accordingly, the polysilicon film 61 is removed and a remaining space becomes the cavity 52.

Specifically, the polysilicon film 61 is dry etched by introducing a XeF₂ gas into a chamber of a dry etching apparatus and evacuating inside of the chamber two to five times, for example.

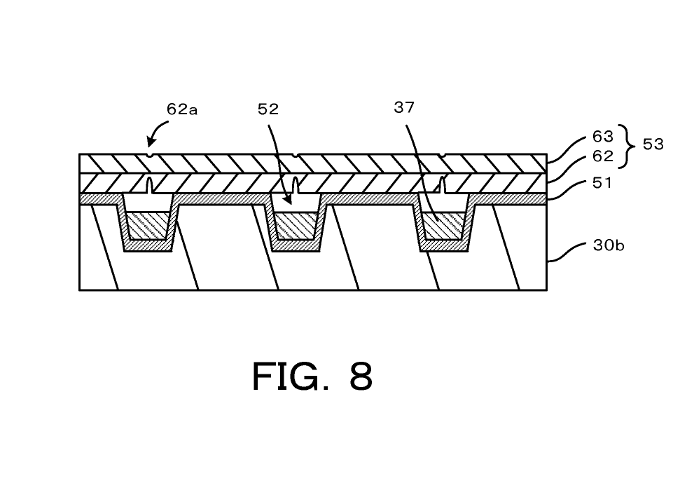

As shown in FIG. 8, a silicon oxide film 63 is formed on the silicon oxide film 62. The silicon oxide film 63 is formed by CVD or LP-CVD. Since the silicon oxide film 63 is deposited on also side walls of the through groove 62a, the through groove 62 is closed and sealed. The silicon oxide film 62 is integrated with the silicon oxide film 63 to obtain, the second insulating film 53d.

A via which reaches an end of the metal resistor 37 is formed to the second insulating film 53, a metal conductor such as gold (Au), copper (Cu), aluminum (Al), and the like is buried into the via and a pad which is connected to the metal conductor is formed on the second insulating film 53. Accordingly, the gauge terminals 38a, 38b can be obtained.

As described above, in the semiconductor device 10 of the embodiment, the semiconductor element 11 has the MOS transistor 13 and the strain gauge unit 14 provided on the semiconductor substrate 12. In the strain gauge unit 14, the metal resistor 37 is buried into the trench 60 formed to the SiC semiconductor layer 30b. Further, the cavity 52 is provided to prevent the metal resistor 37 from coming into contact with the resin 24.

As a result, since the metal resistor 37 faithfully follows expansion and contraction of the semiconductor substrate 12, there is an advantage that a detected strain amount promptly responds and a sensitivity is improved. Thus, the strain amount generated to the semiconductor substrate 12 by the heat generated while electric power is being supplied can be accurately monitored.

A change of connection state between the semiconductor substrate 12 and the substrate 15 via the solder layer 18 is detected from the variation per hour of the strain amount generated to the semiconductor substrate 12 so that thermal fatigue characteristics of the solder layer 18 can be estimated. Accordingly, since breakdown due to thermal fatigue of the solder layer 18 is prevented from occurring, the semiconductor device 10 having high reliability can be obtained.

When the strain gauge unit is formed by forming a metal film on a surface of a semiconductor substrate and patterning the metal film by photolithography, the semiconductor substrate and the metal film are differently expanded and contracted due to a difference of thermal expansion coefficients between the semiconductor substrate and the metal resistor. As a result, there is a possibility that an S/N of a detected strain amount is lowered.

Further, when a metal strain gauge foil is bonded on a surface of a semiconductor substrate by an adhesive, the adhesive is softened at high temperature. As a result, since a following property of a metal resistor to expansion and contraction of the semiconductor substrate is lowered, an improvement of a response speed and a sensitivity of a detected strain amount cannot be expected.

The description has been made here as to the case where the MOS transistor 13 is a vertical MOS transistor. However, other power transistor, for example, a trench gate MOS transistor, an IGBT (Insulated Gate Bipolar Transistor), and a lateral MOS transistor can be also used.

The description has been made as to the case that the semiconductor substrate 12 is a SiC substrate. However, other substrate, for example, a gallium nitride (GaN) substrate, a gallium oxide (Ga₂O₃) substrate, and the like can be also used.

The description has been made as to the case where the metal resistor 37 is dug down lower than the upper surface of the SiC semiconductor layer 30b by the depth d and the cavity 52 is formed below the upper surface of the SiC semiconductor layer 30b. However, the cavity 52 can be also formed above the upper surface of the SiC semiconductor layer 30b.

For example, the polysilicon film 61 acting as the sacrificing layer is formed on the metal resistor 37 without digging down the metal resistor 37 and the silicon oxide film 62 to cover an upper surface and side surfaces of the polysilicon film 61 is formed. Thereafter, the cavity 52 can be formed in the same steps shown in FIG. 7B to FIG. 8.

SiC has such a phenomenon (Kerr effect) that an application of an electric field enables a refractive index to be changed in proportion to a square of an intensity of the electric field. The change of the refractive index of SiC generates a slight strain to SiC.

When a high voltage, such as a surge of several thousands of kilovolts is applied to the semiconductor element 11, the strain gauge unit 14 provided in the SiC semiconductor layer 30b can detect a strain of the semiconductor substrate 12 caused by the surge.

Accordingly, the MOS transistor 13 can be prevented from being broken by ESD (Electro Static Discharge).

### Second Embodiment

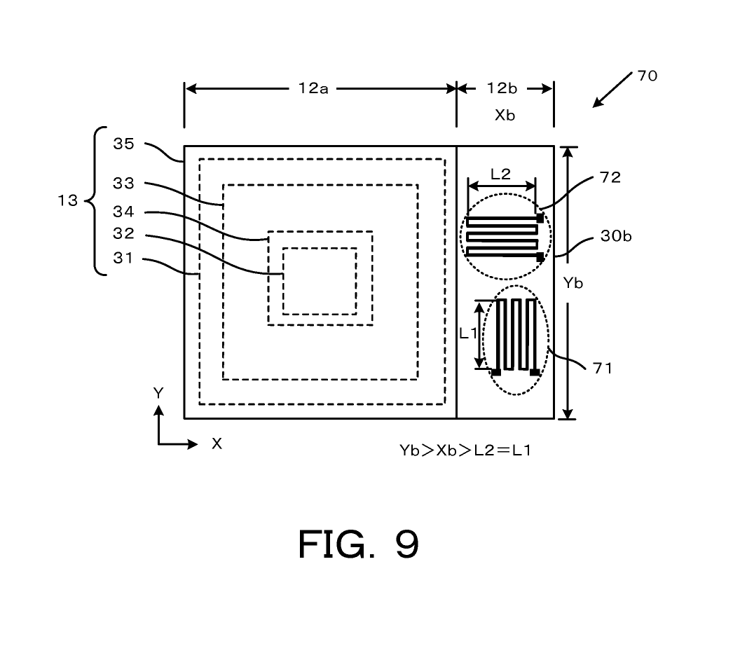

A semiconductor device according to a second embodiment will be described with reference to FIG. 9. FIG. 9 is a plan view showing a semiconductor element employed to the semiconductor device of the embodiment.

In the embodiment, the same configuration portions as those of the first embodiment are denoted by the same reference numerals, a detailed explanation of the same configuration portions is omitted, and different portions will be described. The embodiment is different from the first embodiment in that the semiconductor element has two strain gauge units.

As shown in FIG. 9, the semiconductor element 70 employed to the semiconductor device of the embodiment has a first strain gauge unit 71 and a second strain gauge unit 72 which are provided in a second region 12b of a SiC semiconductor layer 30b. The first and second strain gauge units 71, 72 are provided away from each other along a Y-direction (first direction) and an X-direction (second direction) which are orthogonal to each other.

The first strain gauge unit 71 has a metal resistor (Ni—Cr alloy film) which extends in the Y-direction in the SiC semiconductor layer 30b and is formed in a shape alternately bent in an opposite direction (±Y-direction).

The second strain gauge unit 72 has a metal resistor (Ni—Cr alloy film) which extends in the X-direction in the SiC semiconductor layer 30b and is formed in a shape alternately bent in an opposite direction (±X-direction).

The first strain gauge unit 71 detects a strain amount of the semiconductor substrate 12 in the Y-direction. The second strain gauge unit 72 detects a strain amount of the semiconductor substrate 12 in the X-direction. The strain amount of the semiconductor substrate 12 can be two-dimensionally monitored by the first and second strain gauge units 71, 72.

A change of connection state between the semiconductor substrate 12 and a substrate 15 via a solder layer 18 is two-dimensionally detected from a variation per hour of the two-dimensional strain amounts generated to the semiconductor substrate 12. As a result, it can be expected that an estimation accuracy of thermal fatigue characteristics of the solder layer 18 is increased than the case of one-dimension.

Accordingly, since breakdown due to thermal fatigue of the solder layer 18 is accurately prevented from occurring, reliability of a semiconductor device 10 can be further increased.

Note that since a configuration and a manufacturing method of the first and second strain gauge units 71, 72 are the same as those of the strain gauge unit 14, a description of the configuration and manufacturing method is omitted.

As described above, the semiconductor element 70 of the embodiment 2 is provided with the first and second strain gauge units 71, 72 which are provided in the second region 12b of the SiC semiconductor layer 30b away from each other along the Y-direction and the X-direction which are orthogonal to each other. As a result, the estimation accuracy of the thermal fatigue characteristics of the solder layer 18 is increased so that reliability of the semiconductor device 10 can be further increased.

The second region 12b of the SiC semiconductor layer 30b has a rectangular shape in which a length Yb in the Y-direction is longer than a length Xb in the X-direction (Yb>Xb). Accordingly, a length L2 of the metal resistor of the second strain gauge unit 72 extending in the X-direction is restricted by the length Xb in the X-direction (Xb>L2).

To make a performance of the first strain gauge unit 71 the same as a performance of the second strain gauge unit 72, it is necessary to make a length L1 of the metal resistor of the first strain gauge unit 71 extending in the Y-direction the same as the length L2 (L1=L2).

However, a concern arises in that the performances of the first and second strain gauge units 71, 72 are limited by the length Xb in the X-direction. It is preferable to form the second region 12b in an L-shape in which the second region 12b is provided adjacent to two adjacent sides of a first region 12a.

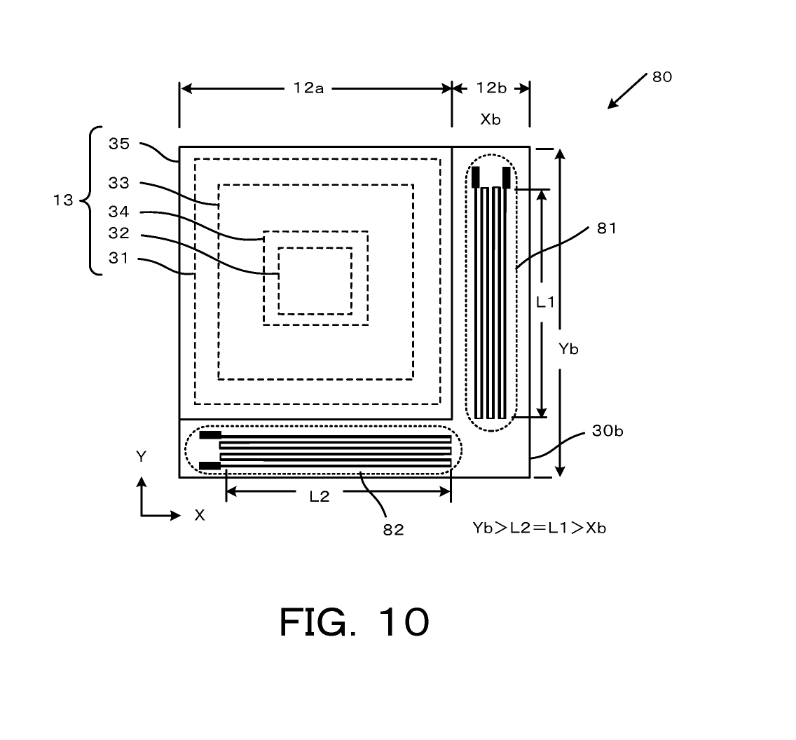

FIG. 10 is a plan view showing a semiconductor element having first and second strain gauge units provided in an L-shaped second region 12b adjacent to the adjacent two sides of the first region 12a. As shown in FIG. 10, a semiconductor element 80 is provided with a first strain gauge unit 81 arranged along a side in a Y-direction of the L-shape of the second region 12b and with a second strain gauge unit 82 arranged along a side in an X-direction.

The first strain gauge unit 81 has a metal resistor (Ni—Cr alloy film) which extends in the Y-direction in the SiC semiconductor layer 30b and has a shape alternately bent in an opposite direction (±Y-direction).

The second strain gauge unit 82 has a metal resistor (Ni—Cr alloy film) which extends in the X-direction in the SiC semiconductor layer 30b and has a shape alternately bent in an opposite direction (±X-direction).

A length L2 of the metal resistor of the second strain gauge unit 82 extending in the X-direction is not restricted by the length Xb in the X-direction shown in FIG. 9 (L2>Xb). A length L1 of the first strain gauge unit 81 extending in the Y-direction and a length L2 of the metal resistor of the second strain gauge unit 82 extending in the X-direction can secure necessary lengths in a length Yb in the Y-direction.

Accordingly, performances of the first and second strain gauge units 81, 82 can be further improved. The semiconductor element 80 is suitable when a chip size has a relative allowance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a semiconductor substrate placed on the substrate and having first and second regions;
an insulating gate field-effect transistor provided in the first region of the semiconductor substrate; and
a strain gauge unit having a long metal resistor provided inside of an upper surface of the semiconductor substrate in the second region of the semiconductor substrate, a first insulating film provided between the semiconductor substrate and the metal resistor and extending up to the upper surface of the semiconductor substrate, and a second insulating film provided above the first insulating film across the metal resistor.

2. The semiconductor device according to claim 1, wherein
the first and second strain gauge units are provided in the second region of the semiconductor substrate, and the first and second strain gauge units are provided away from each other along a first direction and a second direction which are orthogonal to each other.

3. The semiconductor device according to claim 2, wherein
the length of the first strain gauge unit extending in the first direction is substantially the same as the length of the second strain gauge unit extending in the second direction.

4. The semiconductor device according to claim 3, wherein
the second region of the semiconductor substrate is formed in an L-shape adjacent to the first region of the semiconductor substrate along the first and second directions, and the first strain gauge unit is provided along a side of the L-shape in the first direction and the second strain gauge unit is provided along a side of the L-shape in the second direction.

5. The semiconductor device according to claim 4, wherein
the length of the first strain gauge unit extending in the first direction is substantially the same as the length of the second strain gauge unit extending in the second direction.

6. The semiconductor device according to claim 1, wherein
the first region is larger than the second region.

7. The semiconductor device according to claim 1, wherein
an upper surface of the metal resistor is lower than an upper surface of the semiconductor substrate.

8. The semiconductor device according to claim 1, wherein
a cavity is provided between the metal resistor and the second insulating film.

9. The semiconductor device according to claim 1, wherein the semiconductor substrate is a silicon carbide semiconductor substrate.

10. The semiconductor device according to claim 1, wherein
the substrate includes a copper base substrate, an insulating layer provided on the copper base substrate, and a circuit pattern provided on the insulating layer.

11. The semiconductor device according to claim 1, wherein
the semiconductor substrate is placed on the substrate via a metal connection agent.

12. The semiconductor device according to claim 11, wherein
the metal connection agent is a solder.

13. The semiconductor device according to claim 1, further comprising:
a cylindrical case attached to the substrate;
a lid member attached to the case; and
a resin filling the case.

14. A strain monitor, comprising:
a strain measurement device electrically connected to a strain gauge unit of a semiconductor device having a substrate, a semiconductor substrate placed on the substrate and having first and second regions, an insulating gate field-effect transistor provided in the first region of the semiconductor substrate, and the strain gauge unit having a long metal resistor provided inside of a front surface of the semiconductor substrate in the second region of the semiconductor substrate, a first insulating film provided between the semiconductor substrate and the metal resistor and extending up to the front surface of the semiconductor substrate, and a second insulating film provided above the first insulating film across the metal resistor to thereby convert a strain amount generated to the semiconductor substrate to an electric signal; and
a signal processing device electrically connected to the strain measurement device, processing the electric signal in accordance with the strain amount and monitoring a strain in the semiconductor device from a variation per hour of the strain amount.

15. The strain monitor according to claim 14, wherein
the semiconductor device includes first and second strain gauge units provided in the second region of the semiconductor substrate away from each other along a first direction and a second direction which are orthogonal to each other; and
the strain measurement device includes a first strain measurement device electrically connected to the first strain gauge unit and converting a first strain amount generated in a first direction of the semiconductor substrate to a first electric signal and a second strain measurement device electrically connected to the second strain gauge unit and converting a second strain amount generated in a second direction of the semiconductor substrate to a second electric signal.

16. The strain monitor according to claim 15, wherein
the length of the first strain gauge unit extending in the first direction is substantially the same as the length of the second strain gauge unit extending in the second direction.

17. The strain monitor according to claim 15, wherein
the signal processing device is electrically connected to the first strain measurement device and processes the first electric signal in accordance with the first strain amount and is electrically connected to the second strain measurement device and processes the second electric signal in accordance with the second strain amount and monitors a strain in the semiconductor device from two-dimensional variations per hour of the first strain amount and the second the strain amount.

18. The strain monitor according to claim 15, wherein
the second region of the semiconductor substrate is formed in an L-shape adjacent to the first region of the semiconductor substrate along the first and second directions, and the first strain gauge unit is provided along a side of the L-shape in the first direction and the second strain gauge unit is provided along a side of the L-shape in the second direction.

19. The strain monitor according to claim 18, wherein
the length of the first strain gauge unit extending in the first direction is substantially the same as the length of the second strain gauge unit extending in the second direction.
